(19) United States
(12) Patent Application Publication
(10) Pub. No.: US 2026/0101619 A1
(43) Pub. Date: Apr. 9, 2026

(54) LED PACKAGE STRUCTURE

(71) Applicant: HUAIAN AUCKSUN OPTOELECTRONICS TECHNOLOGY CO., LTD, Huaian (CN)

(72) Inventors: Kai CHEN, Huaian City (CN); Ling LU, Huaian City (CN); Jing HUANG, Huaian City (CN)

(21) Appl. No.: 19/405,913

(22) Filed: Dec. 2, 2025

Related U.S. Application Data
(63) Continuation of application No. PCT/CN2024/096911, filed on Jun. 1, 2024.

(30) Foreign Application Priority Data
Jun. 2, 2023 (CN) 202310649515.3

(51) Int. Cl. H10H 20/856; H10H 20/857

(52) U.S. Cl. CPC H10H 20/856; H10H 20/857

(57) ABSTRACT

The present invention discloses an LED package structure, including a first pad structure and a second pad structure that are respectively electrically connected to two electrodes of an LED chip. The first pad structure and the second pad structure are insulated from each other. The first pad structure and the second pad structure are respectively electrically connected to a first polarity electrode and a second polarity electrode of the LED chip. A sum of the bottom area of the first pad structure and the bottom area of the second pad structure is 0.3 to 1 times the bottom area of the package structure of the LED chip. In this solution, a contact area between the chip and a substrate pad is enlarged by growing a larger pad structure under a small-sized chip electrode. This increases placement tolerance and allows direct application of CSP without the need for a conductive plate, thereby improving mounting yield.

### TECHNICAL FIELD

The present invention relates to the field of semiconductor technologies, and in particular, to an LED package structure.

### BACKGROUND

A micro-LED (Mini/MicroLED) display relates to a new novel display technology, and includes millions of tiny LEDs, each of which can emit light independently. This structure enables the micro LEDs to provide high contrast and a wide color gamut. In addition, micro-LED display screens feature high brightness and a fast refresh rate, which make the micro-LED display screens more excellent in display of dynamic images. Compared with conventional LED display screens, the micro-LED display screen does not need a backlight source, because each LED can emit light independently. In this way, the micro-LED display screen can better control the brightness of each pixel, to provide higher contrast and more realistic color. Compared with an OLED display screen, the micro-LED display screen has higher brightness and a longer service life. This is because OLED materials degrade over time while LED materials do not.

However, the micro LED currently faces some technical bottlenecks, for example, low packaging efficiency and yield. The size of a chip used in the micro LED is extremely small, and the area of electrodes is correspondingly small. In the packaging process, it is difficult to accurately control the micro LED chip to achieve correct connection of chip electrodes and substrate pads, and it is difficult to ensure that each LED can be placed correctly.

### SUMMARY

The present invention aims to provide an LED package structure, in which the areas of chip pads are increased, and chip pad structures and electrode structures directly connected to the pads are optimized, to improve placement accuracy of micro chip pads on a substrate, thereby improving packaging efficiency and yield.

The present invention is implemented by using the following technical solutions.

Provided is an LED package structure, including: an LED chip; a fluorescent film covering an upper surface of the LED chip; pad structures arranged on a lower surface of the LED chip; a first reflective layer covering sidewalls of the LED chip; and a second reflective layer covering sidewalls of the LED pad structures. The pad structures include a first pad electrically connected to a first electrode of the LED chip, and a second pad electrically connected to a second electrode of the LED chip. The first pad and the second pad are insulated from each other, a sum of the bottom areas of the pad structures is 0.3 to 1 times the bottom area of a package structure of the LED chip.

Further, the first electrode and/or the second electrode of the LED chip are/is formed from multiple layers of metal, sequentially including a Ti layer, a Cu layer, a Ni layer, and an Au layer, or sequentially including a Cr layer, a Cu layer, a Ni layer, and an Au layer, from an end near the LED chip to an end near the pad structures.

Further, the thickness of the first electrode and/or the second electrode is 1 μm to 100 μm, where the thickness of the Ti layer or the Cr layer is 100 Å to 5000 Å; the thickness of the Cu layer is 1 μm to 100 μm; the thickness of the Ni layer is 1 μm to 10 μm; and the thickness of the Au layer is 200 Å to 5000 Å.

Further, the first pad structure and the second pad structure include an upper metal layer near the LED chip and a lower metal layer away from the LED chip, the upper metal layer is a Cu layer, and the lower metal layer is an Au layer, an Sn layer, or an SnAg alloy layer.

Further, the thickness of the upper metal layer is 1 μm to 100 μm, and the thickness of the lower metal layer is 1 μm to 100 μm; and/or a Cr or Ti adhesion metal layer is further provided between the upper metal layer and the LED chip (2), and the thickness of the adhesion metal layer is 100 Å to 5000 Å; and/or a Ni or Pt barrier layer is further provided between the upper metal layer and the lower metal layer, and the thickness of the barrier layer is 1 μm to 10 μm; and/or the lower metal layer is the SnAg alloy layer, with an Ag content of 0.5% to 3.5%.

Further, the first pad is provided with a first through slot which is not communicated with the first electrode, and/or the second pad is provided with a second through slot which is not communicated with the second electrode.

Further, the first through slot and the second through slot differ in pattern and/or size, to distinguish the first pad and the second pad; the area of the first through slot accounts for 0% to 15% of the area of the first pad; and/or the area of the second through slot accounts for 0% to 15% of the area of the second pad.

Further, distance D2 between the first pad and the second pad is less than or equal to distance D1 between the first electrode and the second electrode, and D2≥150 μm.

Further, an upper end of the first reflective layer is higher than the lower surface of the LED chip, and a lower end of the first reflective layer is flush with the lower surface of the LED chip; and an upper end of the second reflective layer is flush with the lower surface of the LED chip, and a lower end of the second reflective layer is flush with the lower surfaces of the pad structures.

Further, the width of the fluorescent film (1) is greater than the width of the LED chip (2), the width of the fluorescent film is less than the width of the first reflective layer (4), and a top surface of the first reflective layer is flush with a top surface of the fluorescent film (1); and/or the width of the fluorescent film (1) is greater than the width of the LED chip (2), the top surface of the first reflective layer (4) is flush with an upper surface of the LED chip (2), and the fluorescent film (1) covers the upper surface of the LED chip (2) and the top surface of the first reflective layer (4); and/or the width of the fluorescent film (1) is greater than the width of the LED chip (2), the fluorescent film (1) covers the upper surface of the LED chip (2) and covers part of side surfaces of the LED chip (2), and the top surface of the first reflective layer (4) is flush with the bottoms of side surfaces of the fluorescent film (1).

Further, the width of the fluorescent film is greater than the width of the LED chip, the fluorescent film covers an upper surface of the LED chip and covers part of the side surfaces of the LED chip, and the top surface of the first reflective layer is flush with the bottoms of the side surfaces of the fluorescent film.

Further, cup-shaped structures (5) are provided between the first reflective layer (4) and the LED chip (2), and the cup-shaped structures (5) are arranged on peripheral sidewalls of the LED chip (2).

Compared with conventional technologies, the present invention has the following advantages.

Conventional chip electrodes are too small to be directly mounted in an SMD and typically require a support frame during packaging. In this solution, a contact area between the chip and a conductive substrate is enlarged by growing a larger pad structure under a small-sized chip electrode. This increases placement tolerance and allows direct application of CSP without the need for a support frame, thereby improving mounting yield.

An increase in the area difference between the pad structure and the LED electrode leads to an increase in the stress between the pad structure and a first high-reflective white adhesive layer. Therefore, the area of the pad structure needs to be controlled. In addition, the pad structure is slotted, so that the stress can be effectively relieved, and the risk of peeling off is reduced. Moreover, the slots in different shapes are designed to distinguish positive and negative electrodes of the LED.

The pad structure is coated with a second high-reflective white adhesive layer, which protects and improves the stability of the pad structure.

### BRIEF DESCRIPTION OF THE DRAWINGS

FIG. 1 is a diagram of an LED package structure according to Embodiment 1;

FIG. 2 is a diagram of an LED chip structure according to Embodiment 1;

FIG. 3 is a bottom view of FIG. 1;

FIG. 4 is a diagram of an LED package structure according to Embodiment 2;

FIG. 5 is a diagram of an LED package structure according to Embodiment 3;

FIG. 6 is a diagram of growth regions of a first pad and a second pad of an LED package structure according to Embodiment 4; and

FIG. 7 is a diagram of growth regions of a first pad and a second pad of an LED package structure according to Embodiment 5.

In the figures:

1: fluorescent film; 2: LED chip; 2a: upper surface; 2b: lower surface; 2c: sidewall; 210: substrate; 211: N-type semiconductor layer; 212: multi-quantum well layer; 213: P-type semiconductor layer; 214: N-electrode; 2141: first N-electrode; 2142: second N-electrode; 215: P-electrode; 2151: first P-electrode; 2152: second P-electrode; 216: insulation layer; 217: conductive layer; 3: electrode; 4: first reflective layer; 5: cup-shaped structure; 6.1: first pad; 6.11: first through slot; 6.2: second pad; 6.21: second through slot; 7: second reflective layer.

### DETAILED DESCRIPTION

The following clearly and completely describes technical solutions of the present invention with reference to accompanying drawings. Apparently, the described embodiments are some rather than all of embodiments of the present invention. All other embodiments obtained by persons of ordinary skill in the art based on embodiments of the present invention without creative efforts shall fall within the protection scope of the present invention.

In the description of the present invention, it should be noted that orientation or position relationships indicated by the terms such as “center”, “upper”, “lower”, “left”, “right”, “vertical”, “horizontal”, “inner”, and “outer” are based on orientation or position relationships shown in the accompanying drawings, and are used only for ease and brevity of illustration and description of the present invention, rather than indicating or implying that the mentioned apparatus or component needs to have a particular orientation or needs to be constructed and operated in a particular orientation. Therefore, such terms should not be construed as limiting the present invention. In addition, terms “first”, “second”, and “third” are used merely for a purpose of description, and shall not be construed as indicating or implying relative importance.

The present invention is implemented by using the following technical solutions.

### Embodiment 1

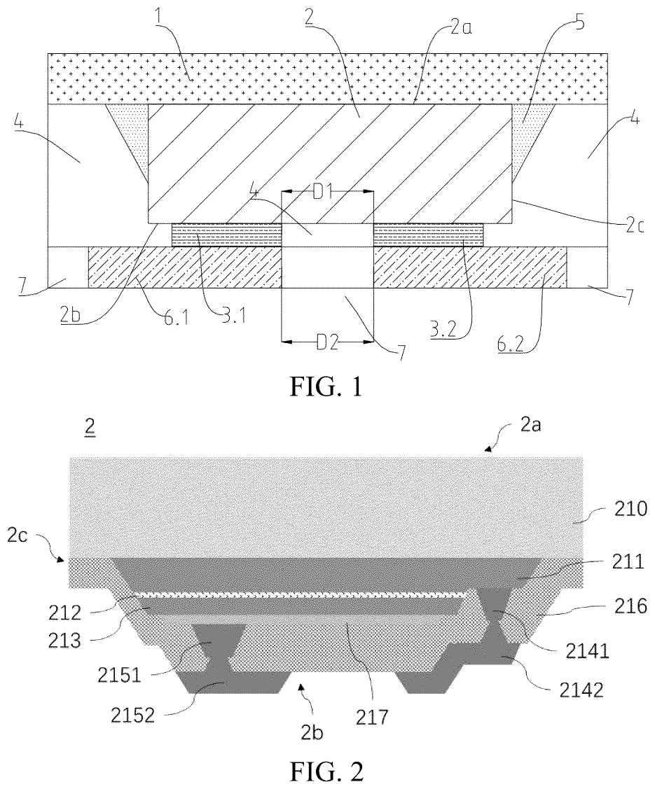

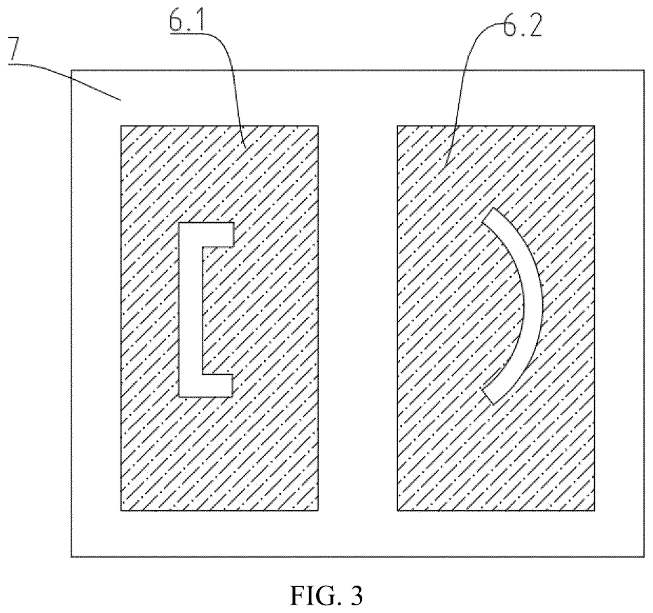

An LED package structure as shown in FIG. 1 includes an LED chip 2, a fluorescent film 1, pad structures 6, a first reflective layer 4, and a second reflective layer 7. The LED chip 2, as a light-emitting unit, includes: an upper surface 2a and a lower surface 2b that are opposite to each other; sidewalls 2c connecting the upper surface 2a and the lower surface 2b; and a first electrode 3.1 and a second electrode 3.2 that are located on the lower surface and separated from each other. The first electrode 3.1 is opposite to the second electrode 3.2, for example, if the first electrode 3.1 is a P-type electrode, the second electrode 3.2 is an N-type electrode; or if the if the first electrode 3.1 is an N-type electrode, the second electrode 3.2 is a P-type electrode. There may be one or more first electrodes 3.1 and one or more second electrodes 3.2 according to design requirements. The fluorescent film 1 is arranged on the upper surface (that is, a light exit surface) of the LED chip 2, and is configured to convert the wavelength of at least part of light emitted by the LED chip 2 into another wavelength. The first reflective layer 4 covers the sidewalls 2c of the LED chip and exposes at least part of a bottom surface of the first electrode 3.1 and at least part of a bottom surface of the second electrode 3.2. The pad structures include a first pad 6.1, electrically connected to the first electrode 3.1; and a second pad 6.2, electrically connected to the second electrode 3.2. In horizontal projection, the first pad 6.1 and the second pad 6.2 have the same shape and have areas respectively greater than areas of the first electrode 3.1 and the second electrode 3.2. Refer to FIG. 3, which is a bottom view of the LED package structure. The second reflective layer 7 covers the sidewalls of the first pad 6.1 and the second pad 6.2 and exposes at least part of a bottom surface of the first pad 6.1 and at least part of a bottom surface of the second pad 6.2.

More specifically, FIG. 2 shows a diagram of a structure of the LED chip 2, which is a flip LED chip 2, and includes an N-type semiconductor layer 211, a multi-quantum well layer 212, a P-type layer 213, and N-electrodes 214 and P-electrodes 215 that are respectively electrically connected to the N-type semiconductor layer and the P-type semiconductor layer. The first electrode 3.1 and the second electrode 3.2 are respectively electrically connected to any one of the N-electrodes 214 and the P-electrodes 215. During preparation, the N-electrodes 214 and the P-electrodes 215 may be formed by a plurality of processes respectively, to form a plurality of N-electrodes and a plurality of P-electrodes, where in this embodiment, the N-electrodes 214 include a first N-electrode 2141 and a second N-electrode 2142 that are electrically connected to each other, and the P-electrodes include a first P-electrode 2151 and a second P-electrode 2152 that are electrically connected to each other; as well as an insulation layer 216, insulating the N-electrode 214 and the P-electrode 215 from each other; and a conductive layer 217, arranged between the P-electrode 215 and the P-type semiconductor layer. Typically, the first N-electrode 2141 and the first P-electrode 2151 are dot-shaped electrodes or finger-shaped electrodes that are arranged in a dispersed manner, and the second N-electrode 2142 and the second P-electrode 2152 are planar electrodes. The first electrode 3.1 and the second electrode 3.2, as connection electrodes for connecting the LED chip and the pad structures, may be prepared in a chip factory, or may be prepared separately before packaging. The first electrode and the second electrode are generally columnar structures with a thickness greater than the thickness of the N-electrode 214 and the P-electrode 215, and the thickness is 1 μm to 100 μm, preferably 30 μm to 70 μm. The first electrode and the second electrode are made from a metal material or a metal alloy, for example, Ti, Ni, Cu, Au, Pt, or a combination thereof. The material is not limited thereto. The insulation layer not only provides electrical insulation between the P-electrode and N-electrode, but also protects the structure of the LED chip. In some embodiments, the insulation layer may also provide reflectivity by, for example, being configured as a DBR structure with slots of different insulating materials, or incorporating a metal reflective layer sandwiched between insulating materials. The conductive layer 217 serves as a current spreading layer, which extends over a surface of the P-type semiconductor layer 213 as widely as possible, is light transmittable, and may be an indium tin oxide (indium tin oxide, ITO) layer or an indium zinc oxide (indium zinc oxide, IZO) layer.

In this embodiment, the first electrode 3.1 and the second electrode 3.2, as structures connecting the LED chip to the first pad 6.1 and the second pad 6.2, are formed from multiple layers of metal, sequentially including a Ti layer, a Cu layer, a Ni layer, and an Au layer, or sequentially including a Cr layer, a Cu layer, a Ni layer, and an Au layer, from an end near the LED chip to an end near the pad structures. The Ti layer or the Cr layer is used as an adhesion layer, and has a thickness of 100 Å to 5000 Å. The Cu layer, as a main constituent of the first electrode 3.1 and the second electrode 3.2, has excellent electric and heat conductivity and has a thickness of 1 μm to 100 μm, preferably 30 μm to 60 μm. The Au layer, as the outermost metal layer, has a thickness of 200 Å to 5000 Å, preferably 650 Å to 950 Å. The Ni layer is arranged between the Cu layer and the Au layer, and has a thickness of 1 μm to 10 μm, preferably 2 μm to 4 μm.

In this embodiment, the first pad 6.1 and the second pad 6.2 completely overlaps the first electrode 3.1 and the second electrode 3.2, and extends toward but does not reach edges of the first reflective layer 4. The shapes of the first pad 6.1 and the second pad 6.2 are rectangular, square, or round in top view, a sum of sizes of the two pads is 0.3 to 1 times, preferably 0.6 to 0.95 times, package size Dw of the LED chip 2. A large pad structure meets heat dissipation requirements and facilitates connection to an external electrode. In another implementation that is not shown, the first pad 6.1 and the second pad 6.2 may extend to the edges of the first reflective layer 4 or beyond the edges of the first reflective layer 4.

Specifically, the first pad 6.1 and the second pad 6.2 each include an upper metal layer near the LED chip 2 and a lower metal layer away from the LED chip. The upper metal layer is a Cu layer, and the lower metal layer is an Au layer, an Sn layer, or an SnAg alloy layer. The thickness of the upper metal layer is 1 μm to 100 μm, preferably 20 μm to 50 μm, and the thickness of the lower metal layer is 1 μm to 100 μm, preferably 20 μm to 50 μm. When the lower metal layer is the SnAg alloy layer, the Ag content is 0.5% to 3.5%.

In an embodiment, a Cr or Ti adhesion metal layer is further provided between the upper metal layer and the LED chip 2, and the thickness of the adhesion metal layer is 100 Å to 5000 Å. In another embodiment, a Ni or Pt barrier layer is further provided between the upper metal layer and the lower metal layer, and the thickness of the barrier layer is 1 μm to 10 μm, preferably 1.5 μm to 4 μm.

The fluorescent film layer 1 may be formed by first mixing a dopant with a colloid to produce a precursor, and then forming the fluorescent film layer through a film forming process. The dopant is phosphor powder, including one or more of KSF powder, nitride phosphor powder, silicate phosphor powder, chlorate phosphor powder, YAG phosphor powder, and sulfide phosphor powder. In this embodiment, because the desired light for the LED package is white light, and the light emitted from the LED chip 2 is blue light, yellow phosphor is needed to convert blue light into white light.

In this embodiment, the reflectivity of the first reflective layer 4 and/or the second reflective layer 7 is greater than 90%, and the material is transparent silicone doped with reflective particles. To be specific, the reflective particles in a high-reflective white adhesive may be insulating particles, such as TiO2, SiO2, or SiN particles, or may be metal particles, such as Al particles, Ag particles, or Cu particles.

Further, distance D2 between the first pad 6.1 and the second pad 6.2 is less than or equal to distance D1 between the first electrode and the second electrode, and D2≥150 μm. If D2 is less than 150 μm, the D2 becomes excessively narrow. This can cause Sn paste to spread and migrate during actual surface-mount use of the first pad 6.1 and the second pad 6.2, resulting in a short circuit due to connection between the first pad 6.1 and the second pad 6.2. The shortest distance D3 between sidewalls of the first pad 6.1 and the second pad 6.2 and sidewalls of the second reflective layer 7 is greater than 0, preferably greater than 100 μm.

The first reflective layer 4 has an upper end flush with an upper surface 2a of the LED chip 2 and a lower end flush with the lower surface of the first electrode 3.1 and/or the second electrode 3.2. The second reflective layer 7 has an upper end flush with the lower surface of the first electrode 3.1 and/or the second electrode 3.2, and a lower end flush with the lower surface of the first pad structure 6.1 and/or the second pad structure 6.2. The fluorescent film 1 has a width greater than the width of the LED chip 2, and covers the upper surface 2a of the LED chip and the top surface of the first reflective layer 4.

Further, in the LED package structure provided by the present invention, cup-shaped structures 5 are provided between the first reflective layer 4 and the LED chip 2. The cup-shaped structures 5 are arranged on peripheral sidewalls of the LED chip 2, and the cup-shaped structures are transparent reflective cavities, preferably, made of transparent silicone.

### Embodiment 2

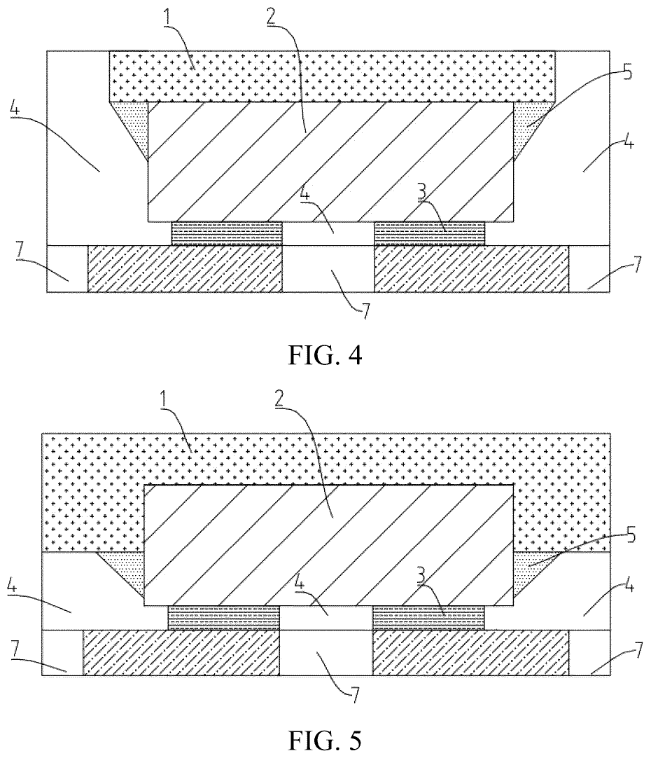

As shown in FIG. 4, the difference between this embodiment and Embodiment 1 is that the fluorescent film 1 is arranged on the upper surface of the LED chip in this embodiment. Due to the presence of dicing channels, the width of the fluorescent film is greater than the width of the LED chip 2. Furthermore, because the package structure of the LED chip in this embodiment includes cup-shaped structures, the width of the fluorescent film 1 is proximately 50 μm to 200 μm greater than the width of the LED chip 2. Then, the cup-shaped structures 5 and the first reflective layer 4 are arranged. The cup-shaped structures are arranged around an upper end of side surfaces of the LED chip 2. The first reflective layer 4 covers sidewalls of the LED chip 2 and sidewalls of the fluorescent film 1, and the top surface of the first reflective layer 4 is flush with the top surface of the fluorescent film. The rest parts have the same structure and are not described again.

Compared with the structure in Embodiment 1, the structure in this embodiment emit light from one single side, but the light-emission angle is narrower (110° to) 120°, and the color temperature distribution of light in space is more concentrated.

### Embodiment 3

As shown in FIG. 5, the difference between this embodiment and Embodiment 1 is that the width of the fluorescent film 1 is greater than the width of the LED chip 2 in this embodiment, and the fluorescent film 1 covers the upper surface of the LED chip and covers part of the side surfaces 2c of the LED chip. The top surface of the first reflective layer 4 is coplanar with the bottom surface of the fluorescent film, and the sidewalls are coplanar with the sidewalls of the fluorescent film. The rest parts have the same structure and are not described again.

Compared with the structure in Embodiment 1, the structure in this embodiment is a structure capable of emitting light from five sides, has a wider light-emission angle of up to 150°, and utilizes the side-emitting light of LEDs, thereby increasing the output brightness.

### Embodiment 4

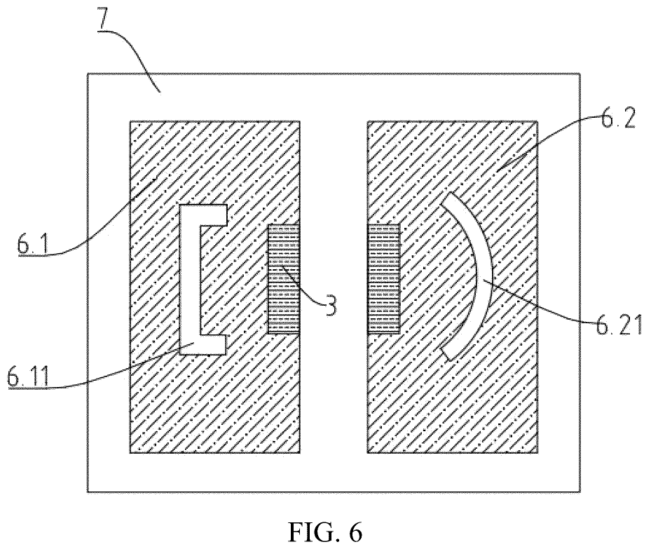

As shown in FIG. 6, the difference between this embodiment and Embodiment 1 is: The first pad 6.1 is provided with a first through slot 6.11, and the second pad 6.2 is provided with a second through slot 6.21. The function of the first through slot 6.11 and the second through slot 6.21 is: Because a difference between areas of the first pad 6.1 and the second pad 6.2 and areas of the first electrode 3.1 and the second electrode 3.2 increases stress between the pads and the high-reflectivity white adhesive of the first reflective layer 4, the through slots are provided in the first pad 6.1 and the second pad 6.2 to effectively relieve the stress, thereby lowering the risk of peeling off of the metal layer. However, the first through slot 6.11 is not communicated with the first electrode 3.1, and the second through slot 6.21 is not communicated with the second electrode 3.2, to avoid electric leakage. Therefore, the first through slot 6.11 and the second through slot 6.21 need to be formed at edge sides away from the first electrode 3.1 and the second electrode 3.2 as shown in this embodiment, or depths of the first through slot 6.1 and the second through slot is less than the thickness of the first pad and the second pad. The first through slot 6.11 and the second through slot 6.21 may be square, circular, arc-shaped, triangular, polygonal or a combination of one or more of the foregoing shapes. In this embodiment, a square shape is used. There may be a plurality of first through slots 6.11 and a plurality of second through slots 6.21, distribute in the first pad 6.1 and the second pad 6.2, and occupying 0% to 15%, preferably 2% to 10%, of the area of the first pad 6.1 and the area of the second pad 6.2, respectively.

In this embodiment, the first through slot 6.11 and the second through slot 6.21 need to be arranged at edge sides away from the first electrode 3.1 and the second electrode 3.2, and the patterns of the first through slot 6.11 and the second through slot are different. The first through slot 6.11 is a U-shaped through slot formed by a plurality of square structures, and the second through slot 6.21 is an arc-shaped through slot, to distinguish the polarities of the first pad 6.1 and the second pad 6.2. Meanwhile, because the first through slot 6.11 and the second through slot 6.21 have different shapes, the areas of the first through slot 6.11 and the second through slot 6.21 are difficult to be made the same, but if the first pad 6.1 and the second pad 6.2 have equal areas, a difference in the areas of the first through slot 6.11 and the second through slot 6.21 is less than or equal to 10%.

### Embodiment 5

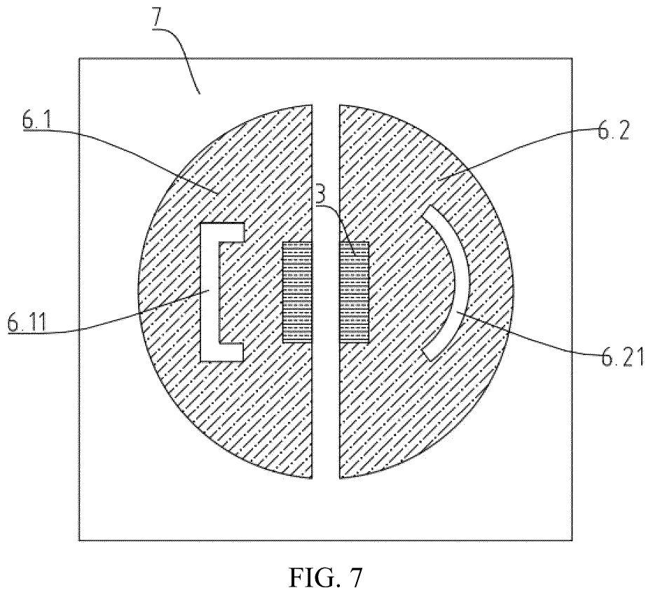

As shown in FIG. 7: the difference between this embodiment and Embodiment 4 is that, in this embodiment, the first pad 6.1 and the second pad 6.2 are two semi-circular discs that are spliced together, and the two electrodes 3 are respectively located at the sides near the straight edges of the semi-circular discs. The rest parts have the same structure and are not described again.

The foregoing embodiments are merely illustrative of the technical concept and features of the present invention, and are intended to enable a person skilled in the art to understand the present invention and to implement same, not to limit the scope of the present invention. All equivalent changes or modifications made according to the spirit of the present invention should be included in the scope of the present invention.

1. An LED package structure, comprising: an LED chip; a fluorescent film covering an upper surface of the LED chip; pad structures arranged on a lower surface of the LED chip; a first reflective layer covering sidewalls of the LED chip; and a second reflective layer covering sidewalls of the LED pad structures, wherein the pad structures comprise a first pad electrically connected to a first electrode of the LED chip, and a second pad electrically connected to a second electrode of the LED chip; the first pad and the second pad are insulated from each other; a sum of the bottom areas of the pad structures is 0.3 to 1 times the bottom area of a package structure of the LED chip; and the area of the first pad and the area of the second pad are respectively greater than the area of the first electrode and the area of the second electrode.

2. The LED package structure according to claim 1, wherein the first electrode and/or the second electrode of the LED chip are/is formed from multiple layers of metal, sequentially comprising a Ti layer, a Cu layer, a Ni layer, and an Au layer, or sequentially comprising a Cr layer, a Cu layer, a Ni layer, and an Au layer, from an end near the LED chip to an end near the pad structures.

3. The LED package structure according to claim 2, wherein the thickness of the first electrode and/or the second electrode is 1 μm to 100 μm, wherein the thickness of the Ti layer or the Cr layer is 100 Å to 5000 Å, the thickness of the Cu layer is 1 μm to 100 μm, the thickness of the Ni layer is 1 μm to 10 μm, and the thickness of the Au layer is 200 Å to 5000 Å.

4. The LED package structure according to claim 1, wherein the first pad and the second pad comprise an upper metal layer near the LED chip and a lower metal layer away from the LED chip, the upper metal layer is a Cu layer, and the lower metal layer is an Au layer, an Sn layer, or an SnAg alloy layer.

5. The LED package structure according to claim 4, wherein the thickness of the upper metal layer is 1 μm to 100 μm, and the thickness of the lower metal layer is 1 μm to 100 μm; and/or
a Cr or Ti adhesion metal layer is further provided between the upper metal layer and the LED chip, and the thickness of the adhesion metal layer is 100 Å to 5000 Å; and/or
a Ni or Pt barrier layer is further provided between the upper metal layer and the lower metal layer, and the thickness of the barrier layer is 1 μm to 10 μm; and/or
the lower metal layer is the SnAg alloy layer, with an Ag content of 0.5% to 3.5%.

6. The LED package structure according to claim 1, wherein the first pad is provided with a first through slot which is not communicated with the first electrode, and/or the second pad is provided with a second through slot which is not communicated with the second electrode.

7. The LED package structure according to claim 6, wherein the first through slot and the second through slot differ in pattern and/or size; the area of the first through slot accounts for 0% to 15% of the area of the first pad; and/or
the area of the second through slot accounts for 0% to 15% of the area of the second pad.

8. The LED package structure according to claim 1, wherein distance D2 between the first pad and the second pad is less than or equal to distance D1 between the first electrode and the second electrode, and D2≥150 μm.

9. The LED package structure according to claim 1, wherein an upper end of the first reflective layer is higher than the lower surface of the LED chip, and a lower end of the first reflective layer is flush with the lower surface of the LED chip; and an upper end of the second reflective layer is flush with the lower surface of the LED chip, and a lower end of the second reflective layer is flush with the lower surfaces of the pad structures.

10. The LED package structure according to claim 9, wherein the width of the fluorescent film is greater than the width of the LED chip, the width of the fluorescent film is less than the width of the first reflective layer, and a top surface of the first reflective layer is flush with a top surface of the fluorescent film; and/or
the width of the fluorescent film is greater than the width of the LED chip, the top surface of the first reflective layer is flush with the upper surface of the LED chip, and the fluorescent film covers the upper surface of the LED chip and the top surface of the first reflective layer; and/or
the width of the fluorescent film is greater than the width of the LED chip, the fluorescent film covers the upper surface of the LED chip and covers part of side surfaces of the LED chip, and the top surface of the first reflective layer is flush with the bottoms of side surfaces of the fluorescent film.

11. The LED package structure according to claim 9, wherein the width of the fluorescent film is greater than the width of the LED chip, the fluorescent film covers the upper surface of the LED chip and covers part of side surfaces of the LED chip, and the top surface of the first reflective layer is flush with the bottoms of side surfaces of the fluorescent film.

12. The LED package structure according to claim 1, wherein cup-shaped structures are provided between the first reflective layer and the LED chip, and the cup-shaped structures are arranged on peripheral sidewalls of the LED chip.
